(19) United States
(12) Patent Application Publication
(10) Pub. No.: US 2017/0152596 A1
(43) Pub. Date: Jun. 1, 2017

(54) SPUTTERING DEVICE AND METHOD OF FORMING THIN FILM USING THE SAME

(71) Applicant: Samsung Display Co., Ltd., Yongin-si (KR)

(72) Inventors: Sang Woo SOHN, Yongin-si (KR); Hyun Ju KANG, Pocheon-si (KR); Chang Oh JEONG, Suwon-si (KR)

(21) Appl. No.: 15/243,162

(22) Filed: Aug. 22, 2016

(30) Foreign Application Priority Data
Nov. 26, 2015 (KR) 10-2015-0166398

(51) Int. Cl. C23C 14/35; H01J 37/34

(52) U.S. Cl. CPC C23C 14/352; C23C 14/35; H01J 37/3405; H01J 37/3417; H01J 37/3455; H01J 37/3441

(57) ABSTRACT

A sputtering device includes a plurality of sputtering targets provided in a process chamber, a substrate holder facing the plurality of sputtering targets and configured to support a substrate, and a deposition mask disposed between the plurality of sputtering targets and the substrate, the deposition mask covering an end portion of the substrate. At least one of the plurality of sputtering targets has an arc shape that is convex toward the substrate and a remainder of the plurality of sputtering targets are flat facing toward the substrate.

### CROSS-REFERENCE TO RELATED APPLICATION

This application claims priority from and the benefit of Korean Patent Application No. 10-2015-0166398, filed on Nov. 26, 2015, which is hereby incorporated by reference for all purposes as if fully set forth herein.

### BACKGROUND

Field

Exemplary embodiments relate to a sputtering device and a method of forming a thin film using the sputtering device.

Discussion of the Background

A sputtering device is widely used to deposit thin films in manufacturing semiconductor elements or liquid crystal displays. However, sputtering devices typically deposit non-uniform film on wide or large substrates resulting in significant defects unsatisfactory for semiconductor elements or liquid crystal displays.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide a sputtering device for generating a uniform thin film by disposing the thin film material on an arc-shaped sputtering target among a plurality of sputtering targets.

Exemplary embodiments also provide a method of forming a uniform thin film using the sputtering device.

Additional aspects will be set forth in the detailed description which follows, and, in part, will be apparent from the disclosure, or may be learned by practice of the inventive concept.

An exemplary embodiment includes a sputtering device. The sputtering device includes a plurality of sputtering targets provided in a process chamber, a substrate holder facing the plurality of sputtering targets and configured to support a substrate, and a deposition mask disposed between the plurality of sputtering targets and the substrate, the deposition mask covering an end portion of the substrate. At least one of the plurality of sputtering targets has an arc shape that is convex toward the substrate and a remainder of the plurality of sputtering targets is flat facing toward the substrate.

An exemplary embodiment includes a method of forming a thin film. The method includes disposing a first electrode, a second electrode, a substrate, an arched sputtering target including a deposition material, and a non-arched sputtering target including the deposition material in a process chamber of a sputtering device, injecting a reaction gas into the process chamber, and applying a first voltage to the first electrode and a second voltage, having a different polarity than the first voltage, to the second electrode to uniformly deposit the deposition material of the arched and non-arched sputtering targets on the substrate.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a schematic cross-sectional view of a sputtering device according to an exemplary embodiment.

FIG. 2 is a schematic perspective view of a sputtering target portion, according to an exemplary embodiment.

FIG. 3 is a schematic cross-sectional view of a deposition state on a substrate by an arc-shaped sputtering target in a sputtering device according to an exemplary embodiment.

FIG. 4 is a schematic cross-sectional view of a magnet disposed under an arc-shaped sputtering target, according to an exemplary embodiment.

FIG. 5 is a flow chart illustrating a method of forming a thin film according to an exemplary embodiment.

### DETAILED DESCRIPTION

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

A sputtering device accelerates plasma ions to have them collide with a sputtering target and have a target material deposited on a substrate. If voltage is applied and argon (Ar) gas or oxygen (O2) gas is injected in an vacuous way, the argon gas or the oxygen gas is ionized and ions collide with the sputtering target. In this instance, the sputtering target outputs atoms that attach to a substrate for semiconductor elements or a substrate for a liquid crystal display. The atoms generate a thin film.

The sputtering device may generate a thin film at a low temperature compared to a chemical vapor deposition (CVD) process performed at a high temperature. The sputtering device may generate a thin film with a relatively simple structure within a short period of time. Thus, a sputtering device is widely used in manufacturing semiconductor elements or liquid crystal displays.

However, when wide a substrate is manufactured, a plurality of sputtering targets are needed as well as an enlarged process chamber. In this instance, plasma is generated in the enlarged process chamber and is not uniformly distributed in the process chamber. Thus, the thin film generated on the substrate is non-uniform. For an oxide-based sputtering target, it is important to acquire a uniform thin film because the oxide-based sputtering target is affected by subtle differences in film quality. In particular, a thickness and density of the thin film deposited on an edge of the oxide-based sputtering target (e.g., a substrate) are reduced by a deposition mask disposed at the edge of the sputtering target causing the thickness and density of the thin film deposited on the edge of the oxide-based sputtering target to be different from the thickness and density of the thin film deposited elsewhere on the sputtering target. In other words, the uniformity of the thin film deteriorates as it is deposited on the substrate causing unsatisfactory defects.

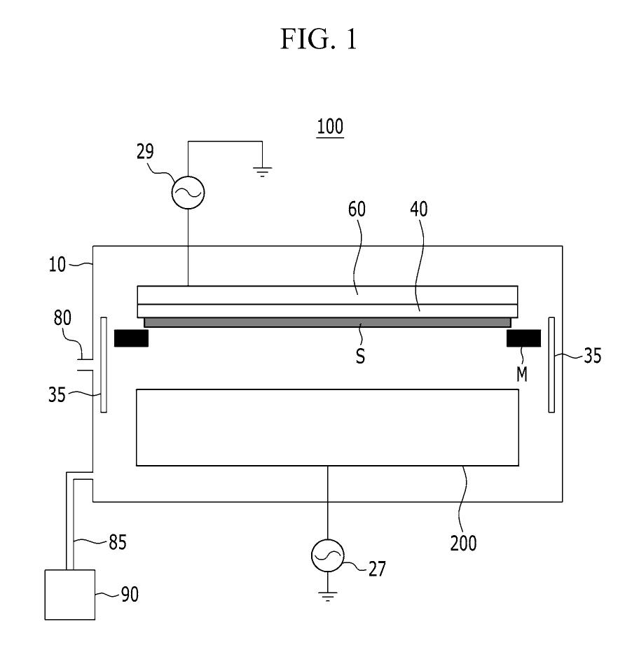

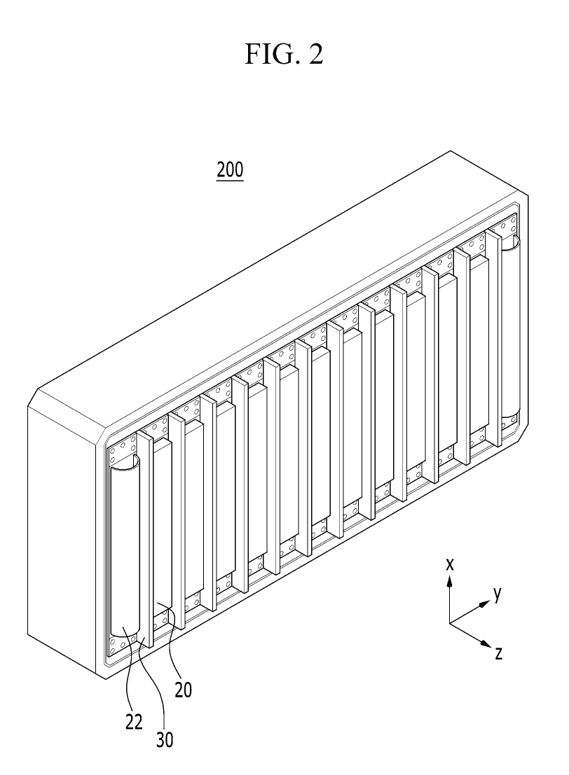

FIG. 1 is a schematic cross-sectional view of a sputtering device according to an exemplary embodiment. FIG. 2 is a schematic perspective view of a sputtering target portion, according to an exemplary embodiment.

Referring to FIGS. 1 and 2, the sputtering device 100 includes a process chamber 10, a sputtering target portion 200, a substrate holder 40, and a deposition mask (M). The sputtering target portion 200 may include sputtering targets 20 and/or 22. The sputtering target portion 200 may include a ground shield 30 disposed between the sputtering targets 20 and/or between sputtering targets 20 and 22.

The process chamber 10 may include a space for a sputtering process. The process chamber 10 may include an injection hole 80 for supplying reaction gas for generating plasma between the sputtering targets 20 and/or 22 and the substrate holder 40. The process chamber 10 may include an exhaust hole 85 for discharging reaction gas to form a high vacuum state, and a vacuum pump 90 connected to the exhaust hole 85. Atmospheric pressure inside the process chamber 10 may be less than or equal to about 1.5 pascal (Pa). For example the pressure inside the process chamber may be less than or equal to about 10⁻³ Pa. The reaction gas may be a noble gas. For example the reaction gas may include at least one of argon (Ar), krypton (Kr), and xenon (Xe). The reaction gas may be injected into the process chamber 10 through the injection hole 80 while maintaining the pressure at several milliTorr (mmTorr) or several millimeters of mercury (mmHg). For example, the reaction gas may be injected into the process chamber 10 while maintaining the pressure of the process chamber at about 1 mTorr to about 10 mTorr (i.e., about 0.133 or about 1.333 Pa).

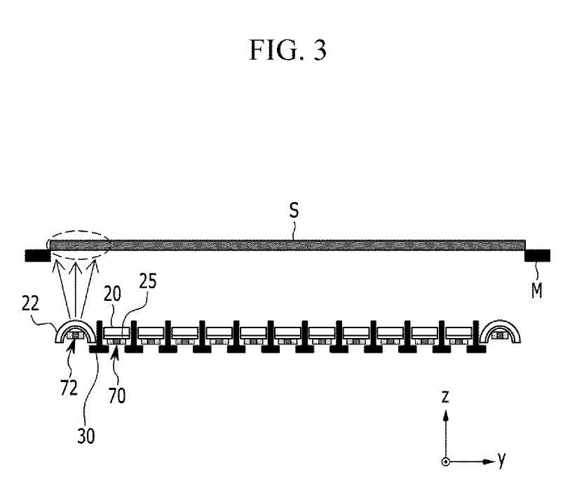

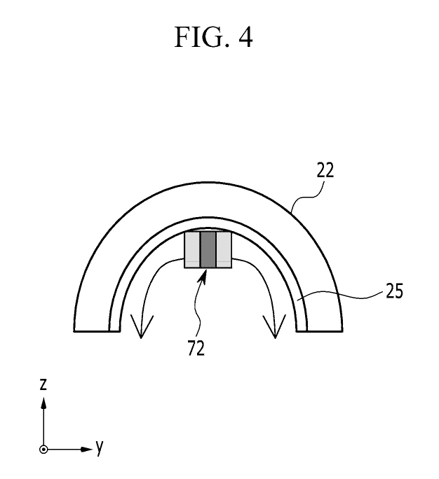

As shown and described later with respect to FIGS. 3 and 4, a target holder 25 may be installed at the bottom of the inside of the process chamber 10 for receiving an alternating current (AC) voltage or a direct current (DC) voltage from a first power source 27. The sputtering targets 20 and 22 including a material to be deposited on the substrate (S), which is supported by the substrate holder 40, may be provided on the target holder 25. The sputtering targets 20 and 22 may include at least one of a metal, an oxide, and a nitride.

The substrate holder 40 may face the sputtering target 20 in the process chamber 10. A second electrode 60 may be disposed on the substrate holder 40 for receiving a voltage from a second power source 29. The second power source 29 may apply a voltage with a potential that is different from a voltage of the first power source 27. For example, a reference voltage may be applied to the second electrode 60 to control plasma and deposit the material of the sputtering target 20 easily.

When the reaction gas is injected into the process chamber 10 through the injection hole 80, voltages with different potentials may be applied to the first electrode (i.e., target holder) 25 (see FIGS. 3 and 4) and the second electrode 60 respectively to generate a plasma discharge. When electrons generated by the plasma discharging collide with the reaction gas in the process chamber 10, the reaction gas may be ionized. The ionized reaction gas may have kinetic energy that corresponds to a potential difference applied between the target holder 25 (see FIG. 4) and the second electrode 60 and may collide with the sputtering targets 20 and 22. When the ionized reaction gas collides with the sputtering targets 20 and 22, electrically neutral atoms of the sputtering targets 20 and 22 may be disposed on substrate (S). Therefore, the atoms of the sputtering targets 20 and 22 may be deposited on the substrate (S).

The deposition mask (M) may be disposed between the sputtering targets 20 and 22 and the substrate (S), and may cover an end portion of the substrate (S). The deposition mask (M) may prevent the material of the sputtering targets 20 and 22 from being deposited on a portion other than the substrate (S), such as the substrate holder 40 or an inner wall of the process chamber 10, and may protect the substrate (S) from physical impacts.

Multiple sputtering targets 20 and 22 may be used, and the sputtering target 22 may be disposed on an end of a plurality of sputtering targets 20. For example, a first sputtering target 22 may be disposed at one end of a plurality of sputtering targets 20 and a second sputtering target 22 may be disposed at the opposite end of the plurality of sputtering targets 20. The sputtering target 22 may have an arc shape in a cross-sectional view taken along y-z plane, which is convex toward the substrate (S). Some or all of the sputtering targets 20 may have a flat shape in a cross-sectional view taken along y-z plane.

The sputtering target 22 with an arc shape enables the atoms of the sputtering target 22 to be more widely emitted toward the substrate (S) and the material of the sputtering target 22 may be uniformly deposited on the end portion of the substrate (S) of which the deposition is hindered by the deposition mask (M).

FIG. 3 is a schematic cross-sectional view of a deposition state on a substrate by an arc-shaped sputtering target in a sputtering device according to an exemplary embodiment. FIG. 4 is a schematic cross-sectional view of a magnet disposed under an arc-shaped sputtering target according to an exemplary embodiment.

Referring to FIG. 3, magnets 70 and 72 may be disposed under the sputtering targets 20 and 22 for retaining plasma generated in the process chamber 10 in an upper space of the process chamber 10 above the sputtering targets 20 and 22. The sputtering targets 20 and 22 may have a rectangular bar shape in x-y plane, and the magnets 70 and 72 may have a rectangular bar shape corresponding to shapes of the sputtering targets 20 and 22.

The magnets 70 and 72 may generate a magnetic field in an upper space of the process chamber 10 above the sputtering targets 20 and 22. The magnets 70 and 72 may hold electrons in the plasma within the magnetic field. The electrons may collide with a reaction gas in the plasma. Electrons of the reaction gas may be separated from the resulting collision such that the plasma may be retained in the upper space of the process chamber 10 above the sputtering targets 20 and 22 through a chain reaction of ionizing the reaction gas.

As shown in FIG. 4, the magnet 72 disposed under the sputtering target 22 with an arc shape may reciprocate along an inner circumference of the sputtering target 22. The magnet 72 may move while a top side of the magnet 72 faces a bottom side of the sputtering target 22. Further, the magnet 72 may move with a velocity of about 30 rpm to 50 rpm. In addition to the magnet 72, the magnet 70 disposed under the sputtering target 20 with a flat shape (shown in FIG. 3) may reciprocate along a bottom side of the sputtering target 20, which is in a y-axis direction.

The substrates (S) supported by the sputtering targets 20 and 22 and the substrate holder 40 may be spaced apart from each other with a gap of about 140 mm to 160 mm.

The sputtering target portion 200 may have two or more sputtering targets. The sputtering target portion 200 may include a ground shield disposed between the sputtering targets. For example, a ground shield 30 may be disposed between the sputtering targets 20 and 22 and a ground shield may be disposed between some or all sputtering targets 20. The ground shields 30 may be extended in a lengthwise direction of the sputtering targets 20 and 22.

The ground shields 30 may be made of a material including titanium and may function to spread the plasma in the process chamber 10.

An auxiliary ground shield 35 (see FIG. 1) may be disposed adjacent to an inner wall of the process chamber 10. The auxiliary ground shield 35 may be disposed between the sputtering targets 20 and 22 and the substrate holder 40. The auxiliary ground shield 35 may allow the plasma generated between the sputtering target 20 and the substrate holder 40 to be uniformly spread to acquire a quality of uniformity of the thin film on the substrate.

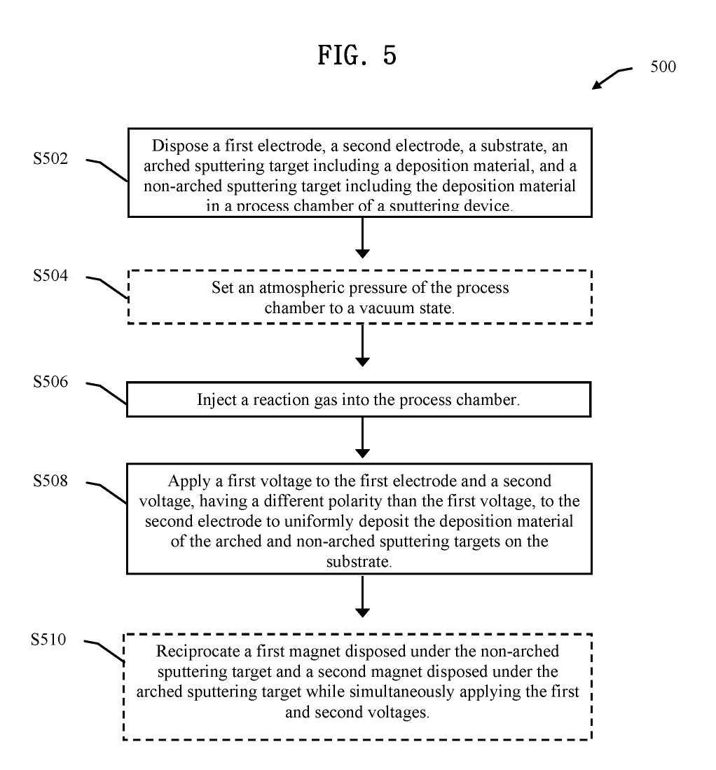

FIG. 5 is a flow chart illustrating a method of forming a thin film according to an exemplary embodiment.

As shown in FIG. 5, a method 500 may include disposing a first electrode, a second electrode, a substrate, an arched sputtering target including a deposition material, and a non-arched sputtering target including the deposition material in a process chamber of a sputtering device (S502). The method 500 may include disposing a sputtering target portion 200 including two arched sputtering targets 22 at opposite ends of a plurality of non-arched sputtering targets 20 (or flat sputtering targets) along with disposing a deposition mask M in the process chamber 10 of a sputtering device 100.

The method 500 may optionally include setting an atmospheric pressure of the process chamber to a vacuum state (S504). The method 500 may include setting the atmospheric pressure of the process chamber 10 to about 1.5 pascal (Pa) or less by using a vacuum pump 90 attached to an exhaust hole 85 of the process chamber 10. The method 500 may include setting the atmospheric pressure inside the process chamber 10 to about 10⁻³ Pa or less. As a another example the method 500 may include setting the atmospheric pressure inside process chamber 10 to about 1 mTorr to about 10 mTorr (i.e., about 0.133 or about 1.333 Pa).

The method 500 may include injecting a reaction gas into the process chamber (S506). The method 500 may include injecting a noble gas through an injection hole 80 in the process chamber 10. The noble gas may be at least one of argon (Ar), krypton (Kr), and xenon (Xe).

The method 500 may include applying a first voltage to the first electrode and a second voltage, having a different polarity than the first voltage, to a second electrode to uniformly deposit the deposition material of the arched and non-arched sputtering targets on the substrate (S508). In particular, the method 500 may include applying a first voltage to the first electrode 25 of the arched and non-arched sputtering targets 22 and 20 and a second voltage, having a different polarity than the first voltage, to the second electrode 60. The application of the first and second voltages generates a plasma discharge. When electrons generated by the plasma discharge collide with the reaction gas in the process chamber 10, the reaction gas may be ionized. The ionized reaction gas may have kinetic energy that corresponds to a potential difference applied between the first electrode 25 (also refer to as the target holder) and the second electrode 60 and may collide with the arched and non-arched sputtering targets 22 and 20. When the ionized reaction gas collides with the arched and non-arched sputtering targets 22 and 20, electrically neutral atoms of the arched and non-arched sputtering targets 22 and 20 may be disposed on substrate (S). Therefore, the atoms of the arched and non-arched sputtering targets 22 and 20 may uniformly be deposited on the substrate (S).

The method 500 may optionally include reciprocating a first magnet disposed under the non-arched sputtering target and a second magnet disposed under the arched sputtering target while simultaneously applying the first and second voltages (S510). In particular, the method 500 may include reciprocating a first magnet 70 under the non-arched sputtering target 20 during the application of the first and second voltages to the first and second electrodes to provide a first magnetic field in an upper space of the process chamber 10 above the non-arched sputtering target 20. Similarly, the method 500 may include reciprocating a second magnet 72 under the arched sputtering target 22 during the application of the first and second voltages to the first and second electrodes to provide a second magnetic field in an upper space of the process chamber 10 above the arched sputtering target 22. The first and second magnetic fields may hold electrons in the plasma discharge so that the electrode of the plasma discharge may collide with electrons of the reaction gas. Electrons of the reaction gas may separate from the resulting collision such that the plasma discharge may be retained in the upper space of the process chamber 10 above the arched and non-arched sputtering targets 22 and 20 through a chain reaction of ionizing the reaction gas. The method 500 may include reciprocating the first magnet 70 along a bottom side of the non-arched sputtering target 20, which is in a y-axis direction. The method 500 may include reciprocating the second magnet 72 at a velocity of about 30 rpm to 50 rpm along an inner circumference of the arched sputtering target 22. The first and second magnets may help uniformly deposited the deposition material on the substrate.

According exemplary embodiments described above, both ends of a plurality of sputtering targets are provided to have an arc shape so that a film-forming range of a material of the sputtering targets deposited on the substrate may be maximized by the sputtering device. In particular, the film-forming uniformity on the end portion of the substrate, of which deposition is hindered by the deposition mask, may be maintained, thereby acquiring a quality of uniformity of the thin film on the substrate.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. A sputtering device, comprising:
a plurality of sputtering targets provided in a process chamber;
a substrate holder facing the plurality of sputtering targets, and the substrate holder configured to support a substrate; and
a deposition mask disposed between the plurality of sputtering targets and the substrate, the deposition mask covering an end portion of the substrate,
wherein at least one of the plurality of sputtering targets has an arc shape that is convex toward the substrate, and a remainder of the plurality of sputtering targets are flat facing toward the substrate.

2. The sputtering device of claim 1, wherein two arc-shaped sputtering targets are disposed on opposite ends of the plurality of sputtering targets having flat shapes.

3. The sputtering device of claim 1, wherein each of the remainder of the plurality of sputtering targets has a rectangular bar shape in a plane facing toward the substrate.

4. The sputtering device of claim 1, further comprising a first magnet disposed under each of the remainder of the plurality of sputtering targets,
wherein the first magnet is configured to retain plasma generated in the process chamber in an upper space of the process chamber that is above each of the remainder of the plurality of sputtering targets.

5. The sputtering device of claim 4, wherein the first magnet has a rectangular bar shape.

6. The sputtering device of claim 5, further comprising a second magnet disposed under at least one arc-shaped sputtering target is configured to reciprocate along an inner circumference of the at least one arc-shaped sputtering target.

7. The sputtering device of claim 6, wherein the second magnet moves while a top side of the second magnet faces a bottom side of the at least one arc-shaped sputtering target.

8. The sputtering device of claim 7, wherein the second magnet moves at a velocity of 30 rpm to 50 rpm.

9. The sputtering device of claim 1, further comprising:
a first electrode supporting the plurality of sputtering targets;
a second electrode connected to the substrate holder; and
plasma generated in the process chamber by applying a first voltage to the first electrode and a second voltage to the second electrode,
wherein the second voltage has an opposite polarity than the first voltage.

10. The sputtering device of claim 1, wherein the sputtering target is spaced apart from the substrate with a gap of 140 mm to 160 mm.

11. The sputtering device of claim 1, further comprising
a ground shield disposed between the plurality of sputtering targets.

12. The sputtering device of claim 11, wherein the ground shield is extended in a lengthwise direction of the plurality of sputtering targets.

13. The sputtering device of claim 11, wherein the ground shield comprises titanium.

14. The sputtering device of claim 11, further comprising
an auxiliary ground shield disposed adjacent to an inner wall of the process chamber.

15. The sputtering device of claim 14, wherein the auxiliary ground shield is disposed between the plurality of sputtering targets and the substrate holder.

16. A method of forming a thin film, the method comprising:
disposing a first electrode, a second electrode, a substrate, an arched sputtering target including a deposition material, and a non-arched sputtering target including the deposition material in a process chamber of a sputtering device;
injecting a reaction gas into the process chamber; and
applying a first voltage to the first electrode and a second voltage, having a different polarity than the first voltage, to the second electrode to uniformly deposit the deposition material of the arched and non-arched sputtering targets on the substrate.

17. The method of claim 16, further comprising reciprocating a first magnet disposed under the non-arched sputtering target and a second magnet disposed under the arched sputtering target while simultaneously applying the first and second voltages,
wherein the first and second magnets retain plasma generated in the process chamber in an upper space of the process chamber above the non-arched and arched sputtering targets.

18. The method of claim 17, wherein the second magnet reciprocates at a velocity of 30 rpm to 50 rpm along an inner circumference of the arched sputtering target.

19. The method of claim 16, further comprising setting an atmospheric pressure of the process chamber is set to a vacuum state.

20. The method of claim 19, wherein the atmospheric pressure of the process chamber is set to about 1.5 pascal (Pa) or less.
